(19) United States
(12) Patent Application Publication
(10) Pub. No.: US 2008/0035835 A1
(43) Pub. Date: Feb. 14, 2008

(54) PHOTOELECTRIC CONVERSION SENSOR

(75) Inventors: Takahiro KOMATSU, Fukuoka (JP); Masakazu MIZUSAKI, Fukuoka (JP); Shinichiro KANEKO, Fukuoka (JP); Masahiro INOUE, Fukuoka (JP); Takashi KITADA, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/836,396

(22) Filed: Aug. 9, 2007

(30) Foreign Application Priority Data
Aug. 10, 2006 (JP) 2006-218073

(51) Int. Cl. H01L 27/00

(52) U.S. Cl. 250/208.1

(57) ABSTRACT

A photoelectric conversion sensor according to the invention comprises: a substrate; a plurality of organic photoelectric conversion pixel parts arranged on the substrate for converting incident light to an electric signal; a light transmissive substrate for transmitting incident light; an optical filter arranged on the light transmissive substrate for limiting the wavelength range of incident light to the plurality of organic photoelectric conversion pixel parts; and a support part for supporting the substrate and the light transmissive substrate in a state where the organic photoelectric conversion pixel parts are separated from the optical filter.

### BACKGROUND

1. Field of the Invention

The present invention relates to a photoelectric conversion sensor for converting an incident light from a subject of imaging such as an original by using organic photoelectric conversion pixels.

2. Description of the Related Art

A photoelectric conversion sensor for converting reflect light from an original or direct light to an electric signal is widely used in a device such as a facsimile or a scanner. The photoelectric conversion sensor comprises a plurality of photoelectric conversion pixels for generating an electric signal having a magnitude corresponding to the intensity of an incident light and an optical system for guiding reflected light from a readout object or direct light to the photoelectric conversion pixels. The photoelectric conversion pixels are mainly photodiodes, photoconductors or phototransistors using inorganic semiconductors or their application components.

Production of such photoelectric conversion pixels requires a large-scale semiconductor process with a very large number of man-hours. Further, it is difficult to increase the size of a semiconductor substrate. As a result, a related art photoelectric conversion sensor is accompanied by a problem that cost reduction is difficult. Thus, as described in (Non-patent Reference 1), an attempt is made to reduce costs by forming photoelectric conversion pixels using an organic photoelectric conversion material.

FIG. 13 is a cross-sectional view of the key sections of a conventional photoelectric conversion pixel. In FIG. 13, a numeral 21 represents a substrate, 22 a first electrode, 23 an organic photoelectric conversion layer, 24 an electron donor layer formed of an electron donor material, 25 an electron acceptance layer formed of an electron acceptance material, and 26 a second electrode.

The organic photoelectric conversion pixel includes, the first electrode 22 formed of a transparent conductive film (such as an ITO film) formed by the sputtering method or resistive heating vapor deposition method on the light transmissive substrate 21 made of a material such as glass, an organic photoelectric conversion layer 23 formed by laminating the electron donor layer 24 and the electron acceptance layer 25 on the first electrode 22 in this order by way of the resistive heating vapor deposition method or the like, and the second electrode 26 including a metal formed on the organic photoelectric conversion layer 23 by the resistive heating vapor deposition method.

When light is irradiated onto an organic photoelectric conversion pixel structured as mentioned above from the substrate 21, absorption of light occurs in the organic photoelectric conversion layer 23 to form exitons. Carriers are separated and electrons move to the second electrode 26 via the electron acceptance layer 25 while positive holes move to the first electrode via the electron donor layer 24. This produces an electromotive force between both electrodes 22 and 26. It is thus possible to extract an electric signal by connecting the electrodes 22, 26 to an external circuit.

FIG. 14 is a schematic view of the cross-sectional structure of a conventional photoelectric conversion sensor. In FIG. 14, a numeral 31 represents a substrate, 32 an optical filter, 33 a protective film, 34 a first electrode, 35 an organic photoelectric conversion layer, and 36 a second electrode. On the substrate 31 is arranged the optical filter 32 formed of a red filter 32R, a green filter 32G and a blue filter 32. The protective film 33 is provided so as to cover the optical filter 32.

The first electrode 34, the organic photoelectric conversion layer 35 and the second electrode 36 are laminated on the protective film 33 in this order.

While it is theoretically possible to laminate the optical filter 32 on an organic photoelectric conversion pixel, a predetermined film-forming process and patterning process are required to form each of the optical filter 32 and the protective film 33. Performing these processes after the organic photoelectric conversion layer 35 has been formed substantially degrades the photoelectric conversion performance of the organic photoelectric conversion layer 35. Thus, a related art photoelectric conversion arranges organic photoelectric conversion pixels on the optical filter 32 as shown in FIG. 14.

Non-patent Reference 1: G. Yu, Y. Cao, J. Wang, J. McElvain and A. J. Heeger, Synth. Met. 102, 904 (1999)

The above related art photoelectric conversion sensor has the following problems.

Film thickness of each of the red filter 32R, the green filter 32G, and the blue filter 32B, shown in FIG. 14, is typically chosen to be some micrometers in order to give desired wavelength selectivity. An attempt to make flat the upper surface of the protective film 33 results in a greater thickness of the protective film 33 and a greater height difference between the first electrode 34 and the substrate 31. The greater height difference results in a greater height difference between the area of wiring positioned on the protective film 33 used to connect the first electrode 34 to an external circuit and the area of the wire positioned on the substrate 31, which is likely to cause a wire break in formation of the wire.

In case the protective film 33 is made thinner in order to reduce the height difference between the first electrode 34 and the substrate 31, asperities occur on the upper surface of the protective film 33 while influenced by the asperities on the upper surface of each of the filters 32R, 32G, 32B, the recess formed between the red filter 32R and the green filter 32G, or the recess formed between the green filter 32G and the blue filter 32B.

The film thickness of the organic photoelectric conversion pixel is as small as 0.5 micrometers. Asperities on the protective film 33 result in variations in the thickness between organic photoelectric conversion pixels or on an individual pixel thus resulting in variations in the photoelectric conversion characteristic of each organic photoelectric conversion pixel. Variations in the photoelectric conversion characteristic of each organic photoelectric conversion pixel could degrade the quality of image data obtained with a photoelectric conversion sensor or produce a short circuit between the first electrode 34 and the second electrode 36.

### SUMMARY

A photoelectric conversion sensor according to the invention comprises: a substrate; a plurality of organic photoelectric conversion pixel parts arranged on the substrate for converting incident light to an electric signal; a light transmissive substrate for transmitting incident light; an optical filter arranged on the light transmissive substrate for limiting the wavelength range of incident light to the plurality of organic photoelectric conversion pixel parts; and a support part for supporting the substrate and the light transmissive substrate in a state where the organic photoelectric conversion pixel parts are separated from the optical filter.

As described above, an optical filter is provided on a light transmissive substrate separate from organic photoelectric conversion pixel part. It is thus possible to reduce the height difference between the electrodes of the organic photoelectric conversion pixel part and the substrate thus reducing possible wire break in a wire on the substrate.

It is made easy to reduce variations in thickness between the organic photoelectric conversion pixels thus upgrading the data reading quality.

### BRIEF DESCRIPTION OF THE DRAWINGS

FIG. 1 is a perspective view showing the external appearance of an image reader according to Embodiment 1.

FIG. 2 is a cross-sectional view showing the internal structure of the image reader according to Embodiment 1.

FIG. 3 is a configuration diagram of the photoelectric conversion unit according to Embodiment 1.

FIG. 4 is a cross-sectional view schematically showing a photoelectric conversion sensor according to Embodiment 1.

FIG. 5 is a cross-sectional view schematically showing a photoelectric conversion sensor according to Embodiment 2.

FIG. 6 is a cross-sectional view schematically showing a photoelectric conversion sensor according to Embodiment 2.

FIG. 7 is a cross-sectional view schematically showing a photoelectric conversion sensor according to Embodiment 4.

FIG. 8 is a cross-sectional view schematically showing a photoelectric conversion sensor according to Embodiment 5.

FIG. 9 is a cross-sectional view schematically showing a photoelectric conversion sensor according to Embodiment 6.

FIG. 10 is a cross-sectional view schematically showing an organic photoelectric conversion layer including a layer where an electron acceptance material is dispersed in an electron donor polymeric material according to Embodiment 8.

FIG. 11 is a configuration diagram of a photoelectric conversion sensor according to Embodiment 9.

FIG. 12 is a configuration diagram of a photoelectric conversion sensor according to Embodiment 10.

FIG. 13 is a cross-sectional view of the key sections of a conventional photoelectric conversion pixel.

FIG. 14 is a schematic view of the cross-sectional structure of a conventional photoelectric conversion sensor.

### DETAILED DESCRIPTION

Embodiments of the invention will be described. These embodiments are available to each other within a related scope.

### Embodiment 1

A photoelectric conversion sensor, a photoelectric conversion unit or an image reader using the photoelectric conversion sensor or photoelectric conversion unit is applicable to a device, such as a facsimile or a scanner, for converting an image of a subject of imaging to an electric signal to obtain image data.

An image reader moves a photoelectric conversion unit and an original relatively from each other and creates image data based on an electric signal outputted from the photoelectric conversion unit while displacing the imaging position of an original. The image reader may be of a reflective type or a transmission type.

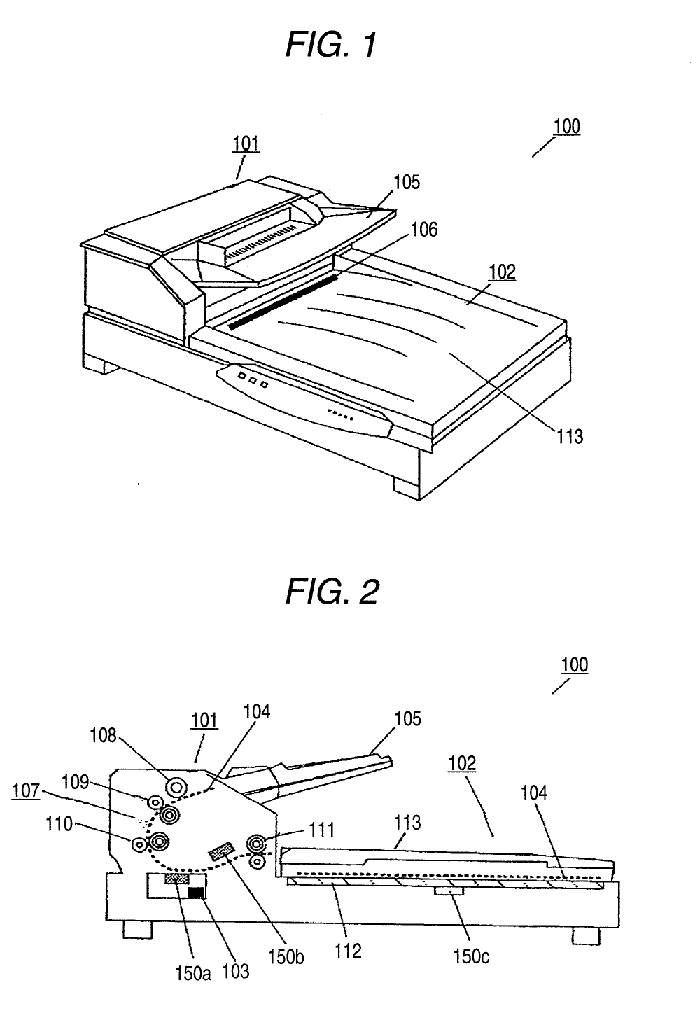

FIG. 1 is a perspective view showing the external appearance of an image reader according to Embodiment 1. FIG. 2 is a cross-sectional view showing the internal structure of the image reader according to Embodiment 1 and shows in this case a scanner as an example of image reader.

As shown in FIGS. 1 and 2, an image reader 100 reads the information in an original 104 from the original 104 by way of photoelectric conversion sensors 150a, 150b, 150c at two points: an automatic original feeding part 101 and a flat bed part 102.

Two photoelectric conversion units 150a, 150b are arranged at the automatic original feeding part 101 and the photoelectric conversion unit 150c is arranged at the flat bed part 102.

The automatic original feeding part 101 houses an original feeder 107 including a guide roller 108 and pairs of guide rollers 109, 110, 111. An original 104 loaded on a paper feed tray 105 is guided between the guide rollers 109 by the guide rollers 108 and is guided between the guide rollers 110 and 111, and is then ejected from a paper output port 106 onto the flat bed part 102.

Both of the two photoelectric conversion units 150a, 150b are arranged between the guide rollers 110 and the guide rollers 111. The photoelectric conversion unit 150a images the original 104 from below the same and converts the obtained image to an electric signal. The photoelectric conversion unit 150b images the original 104 from above the same and converts the obtained image to an electric signal. This supports reading of information on both sides of the original 104 through one transfer pass of the original 104.

The flat bed part 75 has an original tray 112 formed of a transparent material such as glass and an original tray cover 113 for covering the original tray 112 and shielding light. The photoelectric conversion unit 150c is arranged below an original tray 71 and images the original 104 from below the same while traveling in horizontal direction by way of traveling means (not shown) and converts the obtained image to an electric signal.

An image data creation part 103 is connected to the photoelectric conversion units 150a, 150b and 150c and creates image data corresponding to electric signals created by the individual photoelectric conversion units 150a, 150b and 150c.

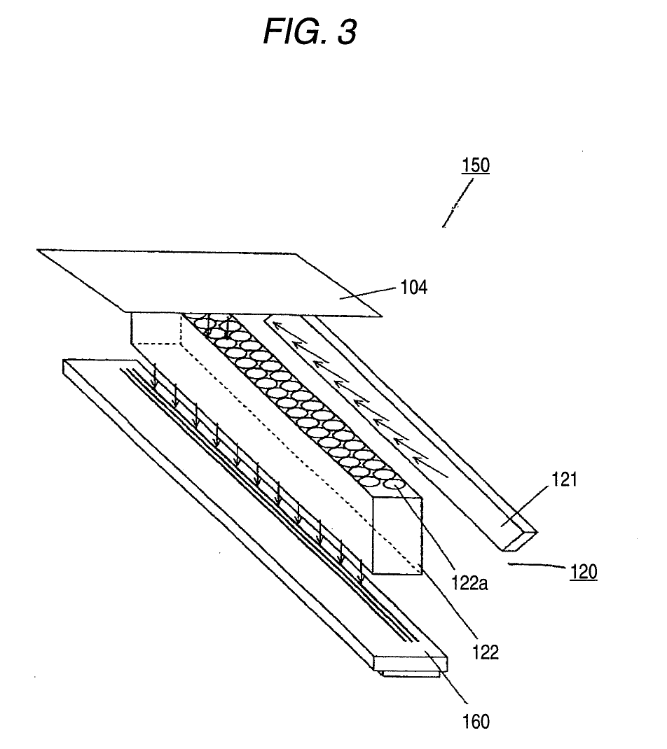

FIG. 3 shows the structure of the photoelectric conversion unit according to Embodiment 1. The figure shows a reflective-type photoelectric conversion unit 150 (150a, 150b, 150c) as an example. Further, FIG. 3 shows an example of a reflective type.

As shown in FIG. 3, the photoelectric conversion unit 150 comprising a photoelectric conversion sensor 160 and an imaging optical system 120 converts an image of the original 104 formed by the imaging optical system 120 to an electric signal by way of the photoelectric conversion sensor 160.

The imaging optical system 120 includes an artificial light source 41 and an optical system 122 for forming an image of light emitted from the artificial light source 121 and reflected on the original 104. The artificial light source 121 may be a linear light source including red light-emitting diode(s), green light-emitting diode(s) and blue light-emitting diode(s) arranged respectively in a predetermined number or a white fluorescent lamp and emits light diagonally upward.

The optical system 122 is for example a rod lens array including a large number of rod lenses 122a. The optical system 122 guides light emitted from the artificial light source 121 and reflected on the original 104 downward in vertical direction and forms an image downward in the vertical direction of the optical system 122.

The photoelectric conversion sensor 160 receives light emitted from the optical system 122 with an internal photoelectric conversion sensor and converts the light to an electric signal.

The artificial light source 121, the optical system 122 and the photoelectric conversion sensor 160 are respectively supported by a single support member (not shown) and maintained in positions shown in FIG. 3.

The image of the original 104 formed by the imaging optical system 120 is converted to an electric signal by the photoelectric conversion sensor 160.

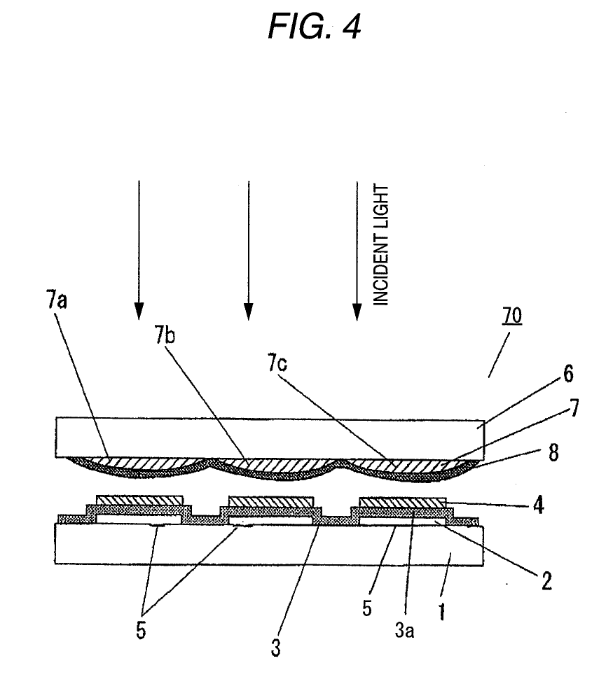

FIG. 4 is a cross-sectional view schematically showing a photoelectric conversion sensor according to Embodiment 1. FIG. 4 shows a photoelectric conversion sensor 70 in the photoelectric conversion sensor 160 (refer to FIG. 3).

In FIG. 4, a numeral 1 represents a substrate on which a plurality of organic photoelectric conversion pixel parts 5 are arranged. On the substrate 1 are mounted a first electrode 2, an organic photoelectric conversion layer 3 and a second electrode 4. The first electrode 2, the second electrode 4 and the organic photoelectric conversion layer 3 (organic photoelectric conversion part 3a) sandwiched by the electrodes form the organic photoelectric conversion pixel part 5.

A numeral 6 represents a light transmissive substrate, 7 an optical filter for transmitting light in a specific wavelength range, and 8 a protective film for transmitting light and protecting the optical filter 7.

The photoelectric conversion sensor 70 includes the substrate 1 with a plurality of organic photoelectric conversion pixel parts 5 arranged thereon and the light transmissive substrate 6 above the plurality of organic photoelectric conversion pixel parts 5. The surface of the light transmissive substrate 6 facing the substrate 1 includes the optical filter 7 and the protective film 8 for covering the optical filter 7.

The substrate 1 and the light transmissive substrate 6 are supported and fixed in integrated state by a support member (not shown) in a state where each organic photoelectric conversion pixel part 5 and the protective film 8 are separated from each other.

The first electrodes 2 of the plurality of organic photoelectric conversion pixel parts 5 are arranged in a matrix in three rows and n columns (n representing an integer equal to or more than 2) on the substrate 1. The single organic photoelectric conversion layer 3 is formed so as to cover all the first electrodes 2. The individual organic photoelectric conversion parts 3a are formed of an area of the organic photoelectric conversion layer 3 positioned on the first electrode 2. FIG. 4 shows a cross-sectional view of three organic photoelectric conversion pixel parts 5 constituting each row in the direction of column assuming that the longitudinal direction is the direction of rows.

The optical filter 7 limits the wavelength range of incident light on each of the plurality of organic photoelectric conversion pixel parts 5. The optical filter 7 includes one or more optical filters arranged on the light transmissive substrate 6, three optical filters 7a, 7b and 7c having different transmission wavelength ranges on the surface facing the substrate 1 in the example of FIG. 4. One optical filter 7a, 7b or 7c corresponds to a single pixel row. To support full-color reading, a red filter for transmitting red light, a green filter for transmitting green light and a blue filter for transmitting blue light are used as filters having different transmission wavelength ranges. The optical filter 7 may be arranged on the surface of the light transmissive substrate 6 opposite to the surface facing the substrate 1.

In the photoelectric conversion sensor 70 arranged below, when incident light enters the light transmissive substrate 6, only the light in the specific wavelength range is transmitted by the optical filter 7 and the transmitted light is received by the organic photoelectric conversion pixel part 5.

On receiving the light, the organic photoelectric conversion pixel part 5 has an electric charge generated thereon, which is transmitted as an electric signal to an external circuit (driving circuit: not shown) from the wire connected to the first electrode 2.

In the photoelectric conversion sensor 70, each of the organic photoelectric conversion pixel parts 5 is arranged on the substrate 1 and the optical filter 7 is provided on the light transmissive substrate 6. Thus, the organic photoelectric conversion pixel part 5 is no longer arranged on the optical filter 7 via a protective film, unlike in the related art. It is thus possible to readily reduce the height difference between the first electrode 2 and the substrate 1. It is also easy to form each of the first electrodes 2 on a flat surface.

With the photoelectric conversion sensor 70, it is readily possible to prevent a wire break in a wire (not shown) used to connect individual organic photoelectric conversion pixel parts 5 to an external circuit in the process of forming the wires on the substrate 1. Further, it is made easy to suppress variations in the thickness between the organic photoelectric conversion pixel parts 5 or variations in the thickness on an individual organic photoelectric conversion pixel part 5. It is also easy to prevent a short circuit between the first electrode 2 and the second electrode 4.

It is thus made easy to produce the photoelectric conversion sensor 70 that will deliver high-quality image data with excellent yield based on the electric signal occurring to each of the organic photoelectric conversion pixel parts 5.

Further, the optical filter 7 is provided on the surface of the light transmissive substrate 6 facing the substrate 1. Thus, it is made easy to place each organic photoelectric conversion pixel part 5 and the optical filter 7 close to each other, and as a result, to cause light in the specific wavelength range that has passed through the optical filter 7a, 7b or 7c to be incident on individual organic photoelectric conversion pixels 5.

The optical filter 7 is covered by the protective film 8 thus suppressing degradation of the optical filter 7.

The photoelectric conversion sensor 70 providing such technical advantages may be manufactured for example in the procedures described below. An exemplary method for manufacturing the photoelectric conversion sensor 70 will be described while citing the reference numerals used in FIG. 4.

First, the organic photoelectric conversion pixel part 5 is formed on the substrate 1 by using a predetermined pattern. In this process, the substrate 1 may use a variety of materials having mechanical or thermal strength. For example, the following materials may be used for the substrate 1: (1) glass; (2) polymeric materials including polyethylene terephthalate, polycarbonate, poly methyl methacrylate, polyethersurfone, polyvinyl fluoride, polypropylene, polyethylene, polyacrylate, amorphous polyolefin and fluorine resin; (3) metals including aluminum (al), gold (Au), chromium (Cr), copper (Cu), indium (In), magnesium (Mg), nickel (Ni), silicon (Si) and titanium (Ti); or (4) Mg alloys including Mg-silver (Ag) alloy and Mg—In alloy, or Al alloys including Al-lithium (Li) alloy, Al-strontium (Sr) alloy and Al-barium (Ba) alloy.

It is effective to use a flexible substrate made of one of the above materials formed into a film or sheet, or a composite substrate made by two or more types of substrates/substrate materials bonded together. While the substrate 1 preferably has electrical insulating properties, the substrate 1 may have electrical conductivity or include a conductive area within a range the operation of the photoelectric conversion sensor 70 is not interfered or depending on the application of the photoelectric conversion sensor 70.

The organic photoelectric conversion pixel part 5 is obtained by forming the first electrode 2, the organic photoelectric conversion layer 3, and the second electrode 4 on the substrate 1 in this order.

The first electrode 2 is obtained for example by forming a metal oxide film, a metal film, an alloy film, or a conductive polymer film on the substrate 1 by way of a physical vapor deposition method (PVD method) such as the sputtering method and patterning the film into a desired shape by way of a combination of a lithography method (photolithography method or electron-beam lithography method) and the etching method.

The above metal oxide film may use a film made of an indium-tin oxide (ITO), an antimony-doped tin oxide (ATO), or an aluminum-doped zinc oxide (AZO). The above metal film may use a film made of aluminum (Al), gold (Au), chromium (Cr), copper (Cu), indium (In), magnesium (Mg), nickel (Ni), silicon (Si) or titanium (Ti). The above alloy film may use a film made of an Mg alloy such as Mg—Ag alloy or Mg—In alloy or an Al alloy such as Al—Li alloy, Al—Sr alloy, or Al—Ba alloy. The above conductive polymer film may use a film made of polyethylene dioxythiophene (PEDOT), polyphenylene vinylene (PPV) or polyfluorene. For example, in case a material with relatively low conductivity such as an allocation-type ITO is used, one area of the first electrode 2 may be formed of a material with high conductivity as required.

For example, the organic photoelectric conversion layer 3 is formed of a layer including at least one type of electron donor material and at least one type of electron acceptance material. The organic photoelectric conversion layer 3 may be formed by various types of vacuum processes such as the vacuum vapor deposition method and the sputtering method or a wet process such as the spin coating method or the dipping method depending on the material used, raw material or structure of the organic photoelectric conversion layer 3. The list-off method may be used in combination as required to form the organic photoelectric conversion layer 3 of a predetermined shape. Considering the low cost as a characteristic of the organic photoelectric conversion pixel part 5, it is preferable to use a wet process that does not require large-scale manufacturing equipment to form the organic photoelectric conversion layer 3.

The above electron donor material may be a polymer such as phenylene vinylene, fluorine, carbazole, indole, pylene, pyrrole, picoline, thiophene, acetylene or diacetylene or its derivatives, and poly-3-hexylthiophene is preferably used for example.

Materials other than a polymeric material may be used. For example, the following materials may be used: (1) porphyrin compounds such as porphine, tetraphenyl porphine copper, phthalocyanine, copper phthalocyanine, and titanium phthalocyanine oxide; (2) aromatic tertiary amines such as 1,1-bis(4-(di-4-p-tolylamino)phenyl)cyclohexane, 4,4′,4″-trymethyl triphenylamine, N,N,N′,N′-tetrakis(p-tolyl)-p-phenylenediamine, 1-(N,N-di-p-torylamino)naphthalene, 4-4′-bis(dimethylamino)-2-2′-dimethyl trifenylmethane, N,N,N′,N′-tetraphenyl-4,4′-diaminobiphenyl, N,N′-diphenyl-N,N′-di-m-toryl-4,4′-diaminobiphenyl, and N-phenylcarbazole; and (3) stilbene compounds such as 4-di-p-tolylaminostilbene and 4-(di-p-tolylamino)-4′-(4(di-p-tolylamino)stylyl)stilbene.

Further, the following material may be used: triazole and its derivatives; oxadiazole and its derivatives; imidazole and its derivatives; polyarylalkane and its derivatives; pyrazolin and its derivatives; pyrazolone and its derivatives; phenylenediamine and its derivatives; arylamine and its derivatives; amino-substituted chalcone and its derivatives; oxazole and its derivatives; styrylanthracene and its derivatives; fluorenone and its derivatives; hydrazone and its derivatives; silazane and its derivatives; polysilane aniline copolymers; styrylamine compounds; aromatic dimethylidine compounds; and poly-3-methylthiophene. It is possible to adjust the absorbing wavelength characteristic of an electron donor material through chemical modification.

The electron acceptance material constituting the organic photoelectric conversion layer 3 may be, on top of a monomeric material or a polymeric material similar to the electron donor material, the following: (i) Fullerene such as C60 or C70 and its derivatives ([5,6]-phenyl C61 acetic acid methyl ester, [6,6]-phenyl C61 acetic acid methyl ester or the like); (ii) carbon nanotube and its derivatives; (iii) oxadiazole such as 1,3-bis(4-tert-buthlphenyl-1,3,4-oxadiazolyl)fenylene and its derivatives; (iv) anthraquinodimetan and its derivatives; (iv) diphenyl quinine and its derivatives. It is possible to adjust the absorbing wavelength characteristic of an electron acceptance material through chemical modification.

The second electrode 4 is a transparent electrode to which light transmission properties are assigned through appropriate selection of the material or film thickness. The second electrode 4 is formed by forming a metal oxide film, a metal film, an alloy film, or a conductive polymeric film on the organic photoelectric conversion layer 3 by way of a physical vapor deposition method (PVD method) such as the sputtering method. Specific examples of these films are same as those mentioned above as examples of the first electrode 2. To form the second electrode 4, a vapor evaporation mask of a predetermined shape is used. The list-off method may be used to form the second electrode 4 of a predetermined shape.

In the manufacturing of the photoelectric conversion sensor 70 shown in FIG. 4, the optical filter 7 is formed on the light transmissive substrate 6 in a process separate from the process to form each organic photoelectric conversion pixel part 5 on the substrate 1.

In this case, the light transmissive substrate 6 may be a plate-shaped object, a sheet-shaped object or a film-shaped object formed of glass or a polymeric material mentioned as an example of the substrate 1.

The optical filter 7 is formed for example by patterning, by way of the photolithography method, a layer formed by an organic composition (such as a color resin) colored with a coloring material such as a desired dye or pigment. Or, the optical filter 7 may be formed by applying a desired organic composition colored with a coloring material onto a predetermined pattern by way of the printing method, the ink-jet method or the vapor evaporation method or by depositing the organic composition on a predetermined location through the electrodeposition method.

In case the protective film 8 is formed on the optical filter 7, the protective film 8 is preferably excellent in the flatness, adhesion, transparency, light-resistance and storage stability. The material of the protective film 8 may be an acrylic, epoxy, poly imide, siloxane, alkyl or other types of photo-setting or thermosetting resin composition. In case the protective film 8 is formed by using a photo-setting or thermosetting resin composition, the resin composition may be applied to form a coating film by way of the spin coating method or printing method and light in a predetermined wavelength range is irradiated onto the coating film or the coating film is subjected to thermal processing for curing to obtain the protective film 8.

In this way, a plurality of organic photoelectric conversion pixel parts 5 are formed on the substrate 1 and the optical filter 7 is formed on the light transmissive substrate 6, and the substrate 1 and the light transmissive substrate 6 are supported and fixed with predetermined support members with the plurality of organic photoelectric conversion pixel parts 5 and the optical filter 7 facing each other thus obtaining the photoelectric conversion sensor 70 shown in FIG. 4.

### Embodiment 2

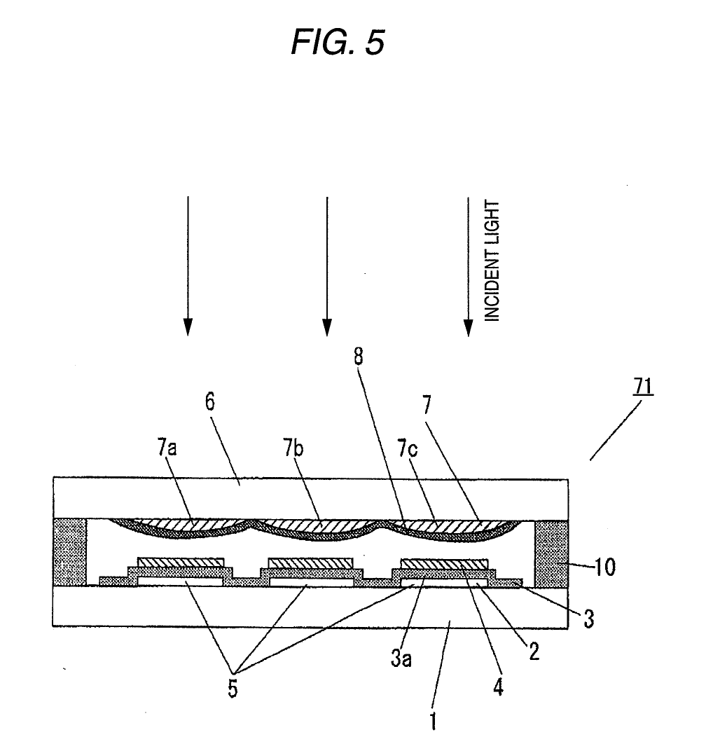

FIG. 5 is a cross-sectional view schematically showing a photoelectric conversion sensor according to Embodiment 2.

As shown in FIG. 5, a photoelectric conversion sensor 71 has a substrate 1 on which a plurality of organic photoelectric conversion pixel parts 5 are mounted and a light transmissive substrate 6 on which an optical filter 7 is mounted bonded together with a moisture-resistant resin 10. That is, FIG. 5 shows the moisture-resistant resin 10 as an example of a support member according to Embodiment 1.

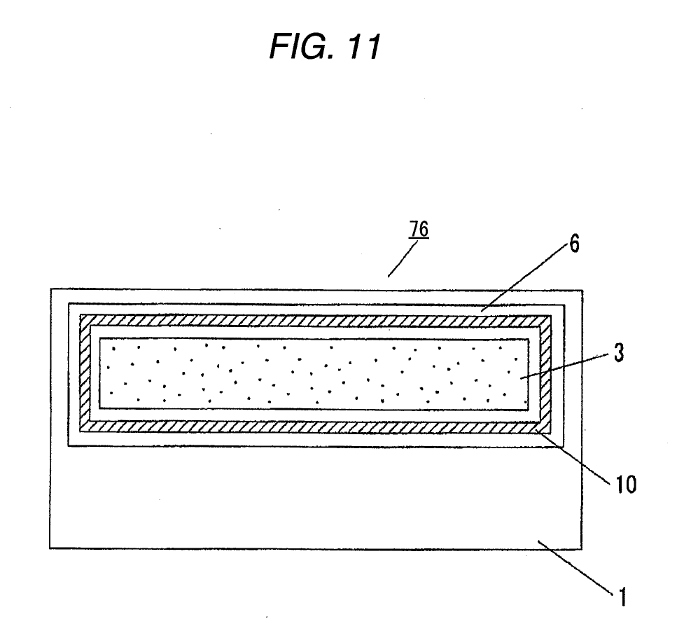

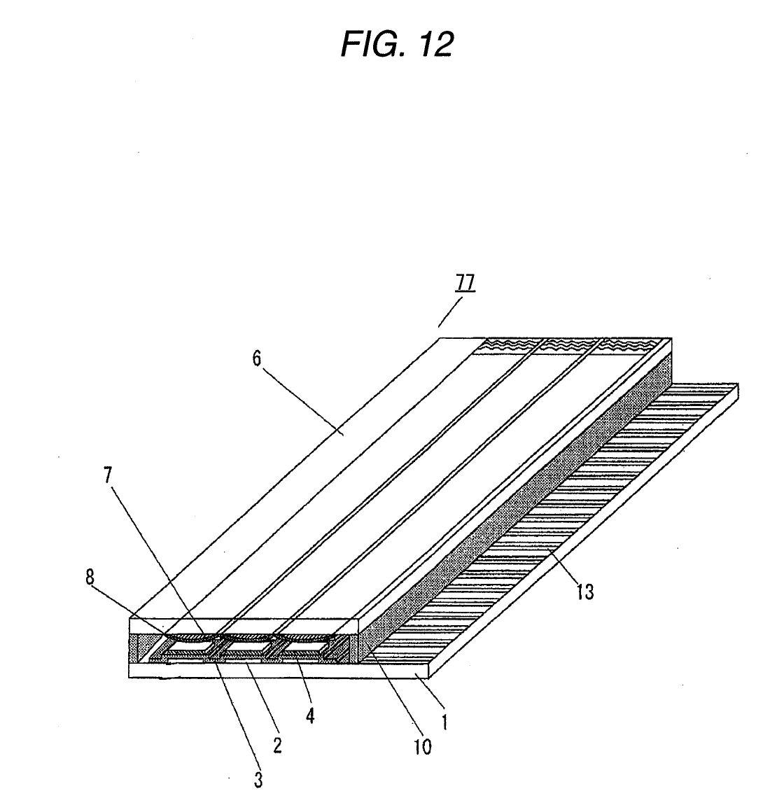

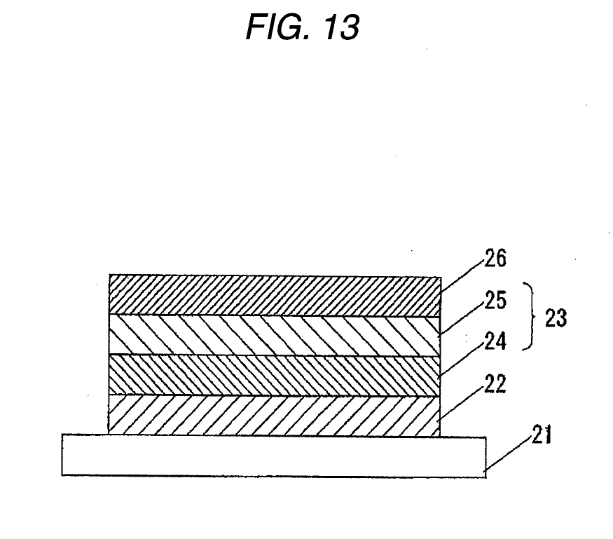

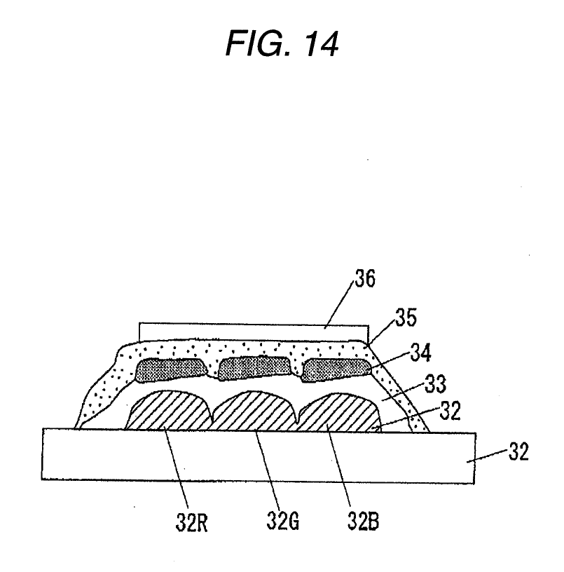

The moisture-resistant resin 10 is formed so as to be bonded to the substrate 1 outside an area in a plan view where the plurality of organic photoelectric conversion pixel parts 5 are arranged and so as to be bonded to the light transmissive substrate 6 outside an area in plan view where the optical filter 7 is arranged. The moisture-resistant resin layer 10 bonds together the substrate 1 and the light transmissive substrate 6 (refer to FIGS. 11 and 12 below). In this way, by forming an enclosed section with the substrate 1, the light transmissive substrate 6 and the moisture-resistant resin layer 10, the organic photoelectric conversion pixel part 5 is sealed. This obtains the moisture-proof effects on the organic photoelectric conversion pixel part 5 and suppresses degradation of the organic photoelectric conversion pixel part 5 caused by invasion of moisture.

The moisture-resistant resin layer 10 is interposed between the substrate 1 and the light transmissive substrate 6 and each organic photoelectric conversion pixel part 5 and the protective film 8 are separated from each other. This prevents degradation of pixels attributable to the contact between the organic photoelectric conversion pixel part 5 and the optical filter 7.

The “moisture-resistant resin” in this embodiment refers to a resin with a low water absorption ratio. The moisture-resistant resin may be a photo-setting resin or a thermosetting resin. It is possible to form the moisture-resistant resin layer 10 with more ease and in a shorter time by using a photo-setting resin.

In case a photo-setting resin is used to form the moisture-resistant resin layer 10, it is necessary to prevent degradation of the organic photoelectric conversion pixel part 5 caused by irradiation of light for photo-curing of the photo-setting resin composition layer as a material of the moisture-resistant resin layer 10. To this end, it is preferable to use a photo mask of a predetermined shape to suppress incidence of the light onto each organic photoelectric conversion pixel part 5.

In case a thermosetting resin is used to form the moisture-resistant resin layer 10, it is necessary to prevent degradation of the organic photoelectric conversion pixel part 5 caused by heat treatment for curing of the thermosetting resin composition layer as a material of the moisture-resistant resin layer 10. To this end, it is preferable to select the makeup of the thermosetting resin composition or heat treatment temperature to allow curing of the thermosetting resin composition layer at a temperature lower than the glass transition point of any organic material used in the organic photoelectric conversion pixel part 5. This prevents each pixel of the organic photoelectric conversion pixel part 5 from being degraded in formation of resin.

The photoelectric conversion sensor 71 of the above structure delivers the same technical effects as the photoelectric conversion sensor described in Embodiment 1. Further, the substrate 1 and the light transmissive substrate 6 are bonded together with the moisture-resistant resin layer 10 and the areas of the organic photoelectric conversion pixel part 5 and the optical filter 7 are surrounded so as to form a sealing space that seals each organic photoelectric conversion pixel part 5 with the substrate 1, the light transmissive substrate 6 and the moisture-resistant resin layer 10. Formation of the sealing space suppresses degradation of the organic photoelectric conversion pixel part 5 attributable to invasion of water. Moreover, when optical filters 7a to 7c constituting the optical filter 7 include an organic pigment or an organic binder, invasion of water into the photoelectric conversion sensor 71 is prevented as described above, which suppresses degradation of the optical filters 7a to 7c attributable to invasion of water.

While it is possible to select the thickness of the moisture-resistant resin layer 10 so as to cause the organic photoelectric conversion pixel part 5 and the protective film 8 to come into contact with each other, it is preferable to select the thickness of the moisture-resistant resin layer 10 so that each organic photoelectric conversion pixel part 5 and the protective film 8 are separate from each other as shown in FIG. 5 from the viewpoint of suppressing degradation of the surface of the organic photoelectric conversion pixel part 5.

The same applies to a case where the protective film 8 is not provided.

### Embodiment 3

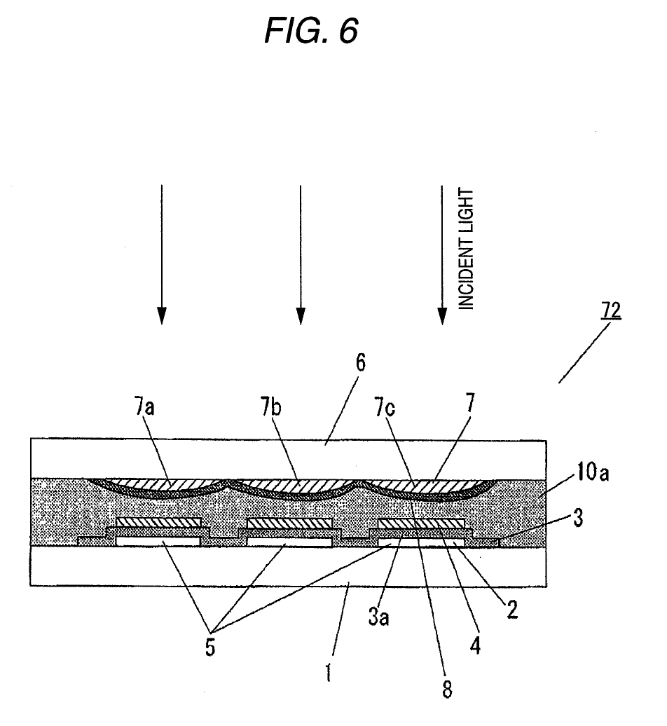

FIG. 6 is a cross-sectional view schematically showing a photoelectric conversion sensor according to Embodiment 2.

In a photoelectric conversion sensor 72 shown in FIG. 6, a moisture-resistant resin layer 10a is formed so as to cover each organic photoelectric conversion pixel part 5 and the moisture-resistant resin layer 10a is used to bond together a substrate 1 and a light transmissive substrate 6. The moisture-resistant resin layer 10a has light transmission properties.

The photoelectric conversion sensor 72 having such a structure delivers the same technical effects as the photoelectric conversion sensor 71 described in Embodiment 2 and is more advantageous in that it is made easy to form the moisture-resistant resin layer 10a.

Same as the moisture-resistant resin layer 10 described in Embodiment 2, the moisture-resistant resin layer 10a may be formed by a photo-setting or thermosetting resin. Extreme care should be taken to prevent degradation or destruction of the organic photoelectric conversion pixel part 5 caused by cure shrinkage, solvent vaporization, and elution of substances while a resin composition is being cured.

In case the moisture-resistant resin layer 10a is formed by a photo-setting resin, it is necessary to prevent incidence of light used for photo-setting of a photo-setting resin composition layer as a material of the moisture-resistant resin layer 10a onto each organic photoelectric conversion pixel part in order to avoid degradation of the organic photoelectric conversion pixel part 5 by the incident light.

### Embodiment 4

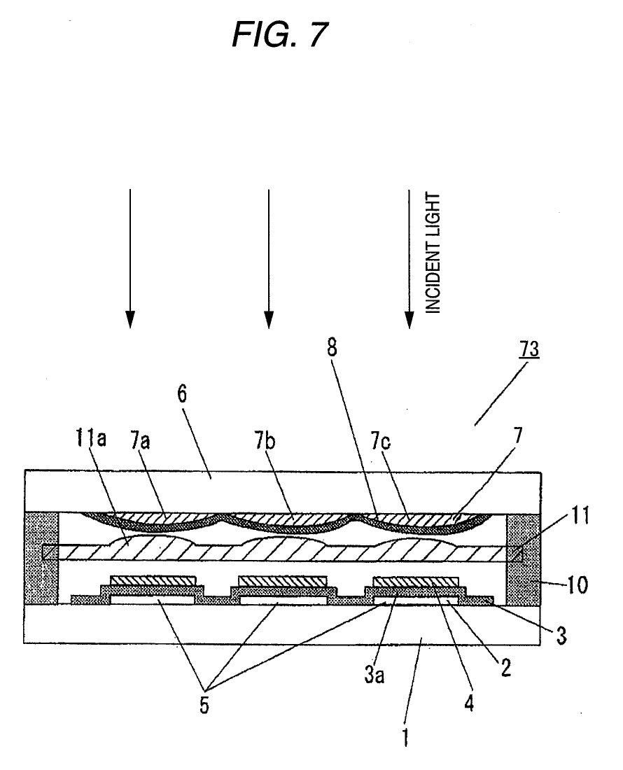

FIG. 7 is a cross-sectional view schematically showing a photoelectric conversion sensor according to Embodiment 4.

As shown in FIG. 7, a photoelectric conversion sensor 70 according to this embodiment has a condensing lens array 11 arranged therein.

In the photoelectric conversion sensor 70, the condensing lens array 11 is supported and fixed by a moisture-resistant resin layer 10 so that it will be positioned between each organic photoelectric conversion pixel part 5 and an optical filter 7. The condensing lens array 11 includes a plurality of condensing lenses 11a. Each condensing lens 11a corresponds to at least one organic photoelectric conversion pixel part 5.

For example, the condensing lens array 11 may be configured so that a single condensing lens 11a will correspond to a single organic photoelectric conversion pixel part 5, or so that a single condensing lens 11a will correspond to a single pixel row.

From the viewpoint of suppressing degradation of the surface of the organic photoelectric conversion pixel part 5, it is preferable to avoid directly arranging another member on the organic photoelectric conversion pixel part 5. However, in case a gap is provided between the optical filter 7 and each organic photoelectric conversion pixel part 5, light that is diffused when passing through an optical filter 7a, 7b or 7c is likely to be incident on a pixel other than a predetermined organic photoelectric conversion pixel part 5. For example, assuming that the optical filters 7a to 7c are respectively a red filter, a green filter and a blue filter, when the light that has passed through the optical filter 7a, 7b or 7c enters a pixel other than the organic photoelectric conversion pixel part 5 corresponding to the optical filter, color smearing could result.

The condensing lens array 11 condenses light that has passed through the optical filter 7 toward a predetermined organic photoelectric conversion pixel part 5. In other words, the condensing lens array 11 condenses light that has passed through the optical filter 7a, 7b or 7c toward an organic photoelectric conversion pixel part 5 corresponding to the optical filter. In a photoelectric conversion sensor 70, the amount of incident light onto each organic photoelectric conversion pixel part 5 increases compared with a case where the condensing lens array 11 is not provided. The above color smearing may be prevented also when the transmission wavelength range differs between optical filters 7a to 7c.

The photoelectric conversion sensor 70 of the above structure delivers the same technical effects as the photoelectric conversion sensor 71 described in Embodiment 2. Further, the light that has passed through the optical filter 7 may be effectively incident on a predetermined organic photoelectric conversion pixel part 5.

The shape or material of each condensing lens 11a of the condensing lens array 11 is not particularly limited but any shape or material may be used that effectively transmits extraneous incident light and condenses the light onto a predetermined organic photoelectric conversion pixel part 5. While it is possible to arrange the condensing lens array 11 in contact with each organic photoelectric conversion pixel part 5, each organic photoelectric conversion pixel part 5 and the condensing lens array 11 are preferably separated from each other from the viewpoint of suppressing degradation of the surface of the organic photoelectric conversion pixel part 5.

### Embodiment 5

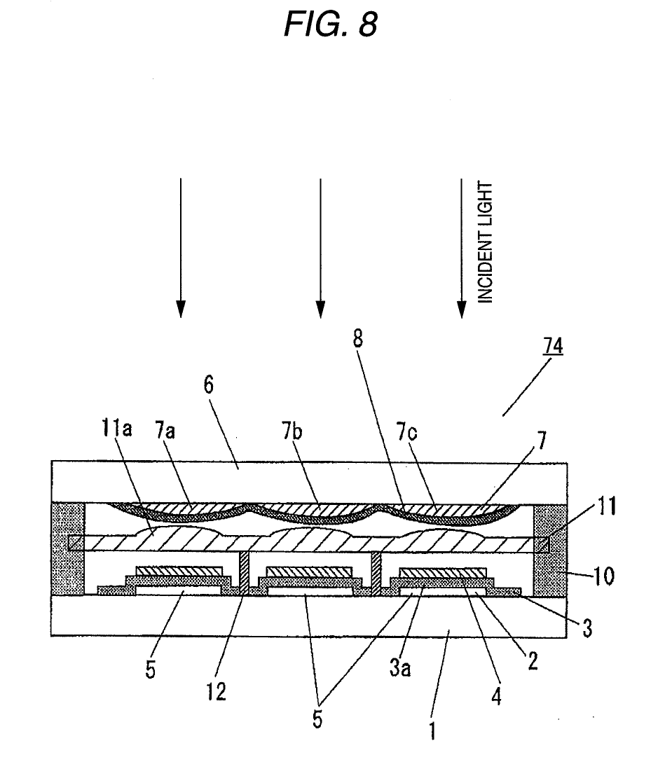

FIG. 8 is a cross-sectional view schematically showing a photoelectric conversion sensor according to Embodiment 5.

As shown in FIG. 8, a photoelectric conversion sensor 74 according to Embodiment 5 arranges a partition part 12 in a position between adjacent organic photoelectric conversion pixels 5.

The plane shape of the partition part 12 is a grating. The height of the partition part 12 from the upper surface of the substrate 1 as a reference plane is greater than that of each organic photoelectric conversion pixel 5. For example, the partition part 12 is formed by forming a film having a predetermined thickness by using an inorganic oxide such as a silicon oxide, an inorganic oxynitride such as silicon oxynitride, or an inorganic nitride such as silicon nitride, or an organic polymeric material such as a poly imide resin and patterning the film into a desired shape by way of a combination of a lithography method (photolithography method or electron-beam lithography method) and the etching method.

Only a single partition part 12 having a plane shape of a grating may be arranged or a plurality of partition parts may be arranged separately from each other. In any way, the height of the partition part 12 from the upper surface of the substrate 1 as a reference place should be selected to be greater than each of the organic photoelectric conversion pixels 5.

The photoelectric conversion sensor 74 of the above structure delivers the same technical effects as the photoelectric conversion sensor 73 described in Embodiment 4. Further, the partition part 12 is included so that it is possible to specify the gap between each organic photoelectric conversion pixel part 5 and a member positioned above (the condensing lens array 11 in the above example) by way of the height of the partition part 12. As a result, cumbersome gap adjustment work required in the manufacturing process is made unnecessary. It is also possible to suppress degradation of the surface of the organic photoelectric conversion pixel part 5 caused by direct contact between each organic photoelectric conversion pixel part 5 and the member positioned above.

Another advantage is prevention of color smearing caused by incidence of light that has passed through the optical filter 7a, 7b or 7c assuming that the optical filters are respectively a red filter, a greed filter and a blue filter, onto a pixel other than the organic photoelectric conversion pixel part 5 corresponding to the optical filter 7a, 7b or 7c. To obtain this technical effect, it is especially preferable to form the partition part 12 with an electrically insulating organic polymeric material (for example a black resist) colored in blacked with a desired coloring material and assign a light shielding feature to the partition part 12.

### Embodiment 6

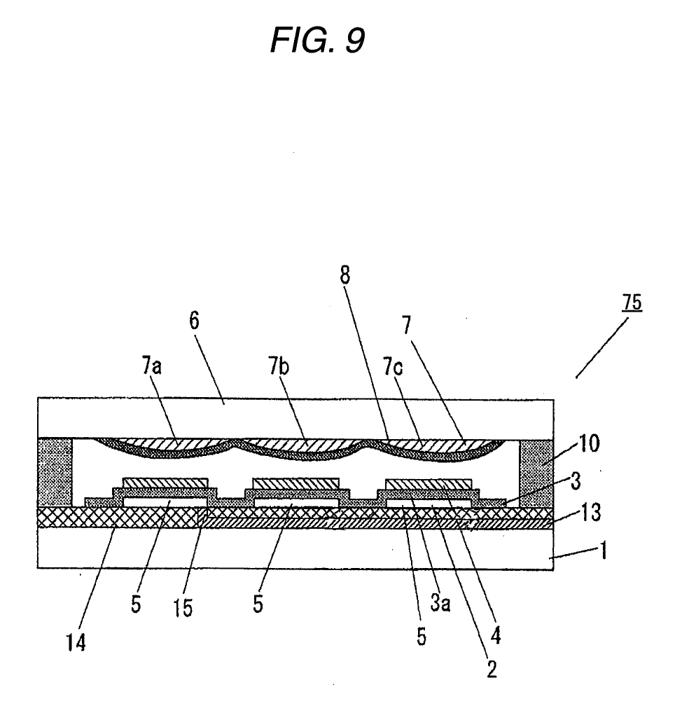

FIG. 9 is a cross-sectional view schematically showing a photoelectric conversion sensor according to Embodiment 5.

As shown in FIG. 9 photoelectric conversion sensor 75 interposes wires 13 for transmitting an electric signal generated on each organic photoelectric conversion pixel part 5 by way of photoelectric conversion to a predetermined external circuit (driving circuit) and an electrically insulating layer 14 for covering the wires 13 between a substrate 1 and a first electrode 2.

The wires 13 for connecting the first electrode 2 to an external circuit (driving circuit: not shown) are arranged one per first electrode 2. The electrically insulating layer 14 is provided to cover the wires 13. Each wire 13 is provided on the substrate 1. Each wire 13 and the first electrode 2 corresponding to the wire 13 are connected to each other with a conductive part 15 that fills a through hole formed in the electrically insulating layer 14.

The conductive part 15 may be formed by the same material as that used to form the first electrode 2 or by a different material. In case the first electrode 2 and the conductive part 15 are formed with the same material, it is possible to form the first electrode 2 and the conductive part 15 at the same time.

With the above structure, it is possible to provide a wide effective area of each pixel in case the pixels of the organic photoelectric conversion pixel part 5 are formed in a plurality of rows and columns on the substrate 1 and the wire 13 is provided from each pixel to the driving circuit.

The photoelectric conversion sensor 75 having such a structure delivers the same technical effects as the photoelectric conversion sensor described in Embodiment 2. Further, each wire 13 is arranged to overlap the first electrode 2 corresponding to the wire 13 in a plan view. It is thus possible to connect the organic photoelectric conversion pixel part 5 to an external circuit (nit shown) while maintaining a wide effective area of each organic photoelectric conversion pixel part 5, and as a result, obtains the technical effect that a high-sensitivity photoelectric conversion sensor is easy to manufacture.

Moreover, the first electrode 2 and the wire 13 corresponding to the first electrode 2 are connected to each other via the conductive part 15. This readily suppresses conduction between the first electrode 2 and the wire 13 corresponding the first electrode at an undesired position.

### Embodiment 7

In this embodiment, the first electrode 2 in each organic photoelectric conversion pixel part 5 is made into a light-reflecting electrode. “The first electrode 2 is made into a light-reflecting electrode.” means that the surface reflectivity of the first electrode 2 is enhanced so as to allow light incident from the organic photoelectric conversion part to be reflected toward the organic photoelectric conversion part with an intensity that will improve the photoelectric conversion efficiency at the organic photoelectric conversion part.

For example, by forming the first electrode 2 with a thick film made of a metal such as aluminum (Al), silver (Ag) or gold (Au) or a desired alloy, it is possible to make the first electrode 2 into a light-reflecting electrode.

With a highly light transmissive film such as a transparent conductive film including an ITO film or a metal thin film, surface reflection takes place, but with a small intensity of reflected light. It is thus difficult to form a light-reflecting electrode by using such a film. The second electrode 4 is a transparent electrode formed by a transparent conductive film including an ITO film or a metal thin film made of a metal such as aluminum (Al), silver (Ag) or gold (Au) or a desired alloy. The structure of the photoelectric conversion sensor is that same as that in any other environment except that the first electrode 2 is made into a light-reflecting electrode.

By making the first electrode 2 into a light-reflecting electrode, the light utilization efficiency (photoelectric conversion efficiency) at each organic photoelectric conversion pixel is enhanced, which readily upgrades the sensitivity of the resulting photoelectric conversion sensor.

### Embodiment 8

While an organic photoelectric conversion layer (organic photoelectric conversion part) of the organic photoelectric conversion pixels of a photoelectric conversion sensor may be formed in a dry process such as co-evaporation of an organic material, a wet process is preferable such as a spin coating method, an ink-jet method or a spray method that does not require large-scale equipment from the viewpoint of cost reduction.

The shape and film quality of a thin film formed in a wet process substantially reflect the influence of the base layer. In case an organic photoelectric conversion pixel is formed on an optical filter as in the related art approach, worsened film quality in the organic photoelectric conversion area may be problematic. The tradeoff obtained is that it is easier to form an organic photoelectric conversion pixel on a smooth base layer by using a separate member as an optical filter as mentioned in other embodiments. In the wet process also, it is easy to form an organic photoelectric conversion layer with excellent smoothness and evenness.

To obtain an organic photoelectric conversion pixel having high photoelectric conversion efficiency, it is preferable to include at least one type of electron donor material and at least one type of electron acceptance material in an organic photoelectric conversion layer (organic photoelectric conversion part). To form an organic photoelectric conversion layer (organic photoelectric conversion part) in a wet process, it is especially preferable to use a polymeric material for at least one of the electron donor material and the electron acceptance material.

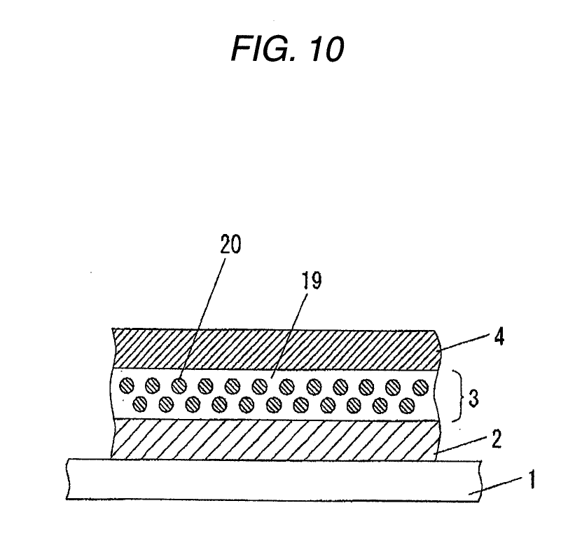

For example, such as the organic photoelectric conversion layer 3 shown in FIG. 10, the organic photoelectric conversion layer 3 including a layer where an electron acceptance material 20 is dispersed in an electron donor polymeric material 19 may be readily formed in a wt process. A composite material obtained by dispersing an electron acceptance material 20 such as fullerenes or carbon nanotube in the electron donor polymeric material 19 may be used to readily form a layer in a wet process and an excellent pn bonding is formed between the electron donor material and the electron acceptance material so that it is preferable as a material of the organic photoelectric conversion layer 3.

In particular, a substance obtained through chemical modification of fullerenes such as [5,6]-phenyl C61 acetic acid methyl ester or [6,6]-phenyl C61 acetic acid methyl ester shows excellent dispersibility in a solvent to the electron donor polymeric material 19 so that it is preferable in obtaining an organic photoelectric conversion layer 3 where the electron acceptance material 20 is uniformly dispersed in a wet process.

### Embodiment 9

FIG. 11 illustrates a photoelectric conversion sensor according to Embodiment 9.

As shown in FIG. 11, in a photoelectric conversion sensor 76, a substrate 1 is larger than a light transmissive substrate 6 in a plan view. Wires are required to transmit an electric signal generated on each organic photoelectric conversion pixel via photoelectric conversion to a predetermined external circuit (driving circuit: not shown). Considering the workability of connecting the wires to the external circuit, the size of the substrate 1 in a plan view on which an organic photoelectric conversion pixel is formed is preferably larger than the size of the light transmissive substrate 6 in a plan view on which an optical filter is formed.

While the substrate 1 is illustrated in a plan view in FIG. 11, the vertical positions of the substrate 1, the light transmissive substrate 6 and the moisture-resistant resin layer 10 are as shown in FIG. 2.

This structure enhances the workability of connecting to a predetermined external circuit the wires used to transmit an electric signal generated on each organic photoelectric conversion pixel by way of photoelectric conversion to the predetermined external circuit.

The external circuit may be mounted on the substrate 1. By mounting the external circuit on the substrate 1, it is made easy to downsize a photoelectric conversion sensor including the photoelectric conversion sensor 76.

### Embodiment 10

FIG. 12 illustrates a photoelectric conversion sensor according to Embodiment 10 showing a case where organic photoelectric conversion pixels of a photoelectric conversion sensor 77 take the pixel arrangement form in a linear image sensor. Same signs are assigned to the same component members as those in FIG. 9. The electrically insulating layer 14, the area of each wire 13 below the organic photoelectric conversion pixel 5, and the conductive part 15 are not shown in FIG. 12. While in FIG. 12 the moisture-resistant resin layer 10 does not seal pixels in order to illustrate pixels for ease of explanation, the surface toward the front is also covered by the moisture-resistant resin layer 10 in case sealing is made as described in Embodiment 2.

In a linear image sensor, pixels (photoelectric conversion elements) are typically arranged over one row and numerous columns, three rows and numerous columns, or four rows and numerous columns. Pixels may be arranged in two rows and numerous columns as required. In an area image sensor, pixels (photoelectric conversion elements) are arranged over numerous rows and numerous columns.

In the photoelectric conversion sensor 77 shown in FIG. 12, a large number of organic photoelectric conversion pixels 5 are arranged over three rows and numerous columns. The size of the substrate 1 in a plan view is larger than the size of the light transmissive substrate 6 in a plan view and one end of each wire 13 extends outside the light transmissive substrate 6 in a plan view. An external circuit (driving circuit: not shown) for processing an electric signal generated on each organic photoelectric conversion pixel part 5 by way of photoelectric conversion is mounted on the substrate 1, for example.

For a photoelectric conversion sensor including such a photoelectric conversion sensor 77, the photoelectric conversion sensor is arranged in combination with a light source shown in FIG. 3 and a predetermined optical system to form a photoelectric conversion unit. In the photoelectric conversion unit, light reflected on a readout object such as an original or direct light enters the light transmissive substrate 6 via a predetermined optical system, passes through the optical filter 7 and then enters the organic photoelectric conversion pixel part 5. This generates an electric signal having the magnitude corresponding to the incident light amount on the organic photoelectric conversion pixel part 5. The electric signal generated on the organic photoelectric conversion pixel part 5 is transmitted to the external circuit via the wires 13 and predetermined image data is generated.

The above light source may be any light source as long as it can uniformly irradiate light onto a readout object. A xenon lamp, a light-emitting diode, a cathode-ray tube, an inorganic EL (electroluminescence) element, or an organic EL element is used.

The above optical system may be any optical system as long as it can efficiently guide light reflected on a readout object or direct light to a photoelectric conversion sensor and its material or shape is not particularly limited. In case a close-contact type photoelectric conversion unit is used, an erecting and unmagnifying lens such as the Selfoc lens (trademark: from Nippon Sheet Glass) array is preferably used. Any external circuit may be used as long as it can detect a minute output from each organic photoelectric conversion pixel part 5 and create image data based on the output.

While a photoelectric conversion sensor according to each embodiment has been described, the invention is not limited to the foregoing embodiments.

For example, a negative pole buffer layer made of a substance that has a higher work function than an electron acceptance material constituting an organic photoelectric conversion layer including metal fluorides such as lithium fluoride or metal oxides and also a substance that has a lower work function than the first electrode may be interposed between the first electrode and the organic photoelectric conversion part as required. Similarly, a positive pole buffer layer made of a substance that has a higher work function than an electron donor material constituting an organic photoelectric conversion layer as well as the second electrode may be interposed between the second electrode and the organic photoelectric conversion part as required.

The optical filter may include at least three types of optical filters whose transmission wavelength range differs from each other. Or, the optical filter may include a monochromatic optical filter alone as an optical filter. In case the optical filter includes at least three types of optical filters, the at least three types of optical filters may include primary color filters, that is, a red filter, a green filter and a blue filter or complementary color filters, that is, a cyan filter, a magenta filter, and a yellow filter.

In case the optical filter includes a monochromatic optical filter alone, the monochromatic optical filter may be arranged in one-to-one relationship with pixel rows or one monochromatic optical filter may be arranged to support all pixels rows.

In the bonding of a substrate and a light transmissive substrate by using a moisture-resistant resin layer such as in the photoelectric conversion sensor according to Embodiment 2 or 3, it is possible to add a desired filler to the moisture-resistant resin to adjust the thermal expansion coefficient of the moisture-resistant resin layer (including the filler) and suppress displacement of each organic photoelectric conversion pixel and the optical filter corresponding to the organic photoelectric conversion pixel caused by variations in the ambient temperature.

The information reading sensor according to the invention may be subjected to various changes, modifications or combinations on top of alterations described above.

The manufacturing process for the photoelectric conversion sensor according to Embodiment 2 will be described in detail.

First, the sputtering method is used to form an aluminum film 100 nm thick on a glass substrate. A resist material (OFPR-800 (product name) from TOKYO OHKA KOGYO CO., LTD.) is applied to the aluminum film by using the spin coating method to form a resist film having thickness of 2 micrometers. Selective exposure and development are made on the resist film to obtain a resist pattern of a predetermined shape. The glass substrate on which the resist pattern is formed is immersed in a mixed acid of phosphoric acid, acetic acid and nitric acid. Etching is applied to the aluminum film in the portion without a resist pattern formed. Rinsing with pure water is made and the resist pattern is removed to obtain a large number of first electrodes made of an aluminum film having a predetermined shape. These first electrodes are arranged in a matrix over three rows and numerous columns.

Next, by using Semicoclean (product name) from Furuuchi Chemical Corporation, ultrasonic cleaning is made for five minutes on the glass substrate on which the first electrode is formed, followed by ultrasonic cleaning for 10 minutes using pure water and then removal of deposited water using a nitrogen blower and drying at 250° C.

Next, a chlorobenzene solution including poly(2-methoxy-5-(2′-ethylhexyloxy)1,4-phenylenevinylene) (hereinafter abbreviated as “MEH-PPV”) functioning as an electron donor polymeric material and [6,6]-phenyl C61 acetic acid methyl ester (hereinafter abbreviated as “[6,6]-PCBM”) functioning as an electron acceptance material at weight ratio of 1:4 is sin-coated on each first electrode, followed by heating for 30 minutes in a clean oven at 100° C. to obtain an organic photoelectric conversion layer about 100 nm thick.

[6,6]-PCBM is a chemically modified fullerene and shows excellent dispersibility in chlorobenzene as a solvent to MEH-PPV so that it is preferably used to form a homogeneous organic photoelectric conversion layer. The electron accepting properties of [6,6]-PCBM are very high so that transfer of optical carriers is efficiently made between [6,6]-PCBM and MEH-PPV as an electron donor polymeric material.

The glass substrate on which an organic photoelectric conversion layer is formed is placed in a sputtering unit and is subjected to decompression until a degree of vacuum of 0.68 mPa (5×10⁻⁶ Torr) or below is obtained. Then a large number of second electrodes made of ITO 150 nm in film thickness are formed on the organic photoelectric conversion layer. The film forming atmosphere is a mixed atmosphere of Argon (Ar) gas and Oxygen (O₂) gas (Ar/O₂=100/3.5) and the pressure of the mixed atmosphere is 0.27 Pa (2×10⁻³ Torr). A dc power of 300 W is supplied to the target and the sputtering time is three minutes.

Through formation of the second electrodes, a large number of organic photoelectric conversion pixels are formed on the glass substrate. Each organic photoelectric conversion pixel includes a first electrode made of an aluminum film, an organic photoelectric conversion part including an area of the organic photoelectric conversion layer above the first electrode, and a second electrode including an ITO film formed on the organic photoelectric conversion part.

Separately from formation of the organic photoelectric conversion pixels, a light transmissive substrate having an optical filter formed on one surface is fabricated. The optical filter includes a plurality of optical filters arranged in a predetermined pattern. Each optical filter is covered by a protective film.

After that, a glass substrate including a large number of organic photoelectric conversion pixels formed thereon is bonded to the light transmissive substrate including an optical filter formed thereon by using a moisture-resistant resin layer made of a photo-setting resin to obtain the photoelectric conversion sensor shown in FIG. 5.

As described above, an optical filter is provided on a light transmissive substrate separate from organic photoelectric conversion pixel part. It is thus possible to reduce the height difference between the electrodes of the organic photoelectric conversion pixel part and the substrate thus reducing possible wire break in a wire on the substrate. It is made easy to reduce variations in thickness between the organic photoelectric conversion pixels thus upgrading the data reading quality.

This application is based upon and claims the benefit of priority of Japanese Patent Application No 2006-218073 filed on Jun. 8, 1910, the contents of which are incorporated herein by reference in its entirety.

What is claimed is:

1. A photoelectric conversion sensor comprising:
a substrate;
a plurality of organic photoelectric conversion pixel parts arranged on said substrate for converting incident light to an electric signal;
a light transmissive substrate for transmitting incident light;
an optical filter arranged on said light transmissive substrate for limiting the wavelength range of incident light to said plurality of organic photoelectric conversion pixel parts; and
a support part for supporting said substrate and said light transmissive substrate in a state where said organic photoelectric conversion pixel parts are separated from said optical filter.

2. The photoelectric conversion sensor according to claim 1, wherein said optical filter is arranged on the surface of said light transmissive substrate facing said substrate.

3. The photoelectric conversion sensor according to claim 1, wherein said optical filter includes a plurality of optical filters having different transmission wavelength ranges.

4. The photoelectric conversion sensor according to claim 1, wherein said optical filter includes a red filter for transmitting red light, a green filter for transmitting green light and a blue filter for transmitting blue light.

5. The photoelectric conversion sensor according to claim 1, further including a protective film for covering said optical filter,
wherein said protective film has light transmission properties.

6. The photoelectric conversion sensor according to claim 1, wherein said support part is a moisture-resistant resin layer for bonding together said substrate and said light transmissive substrate and that said moisture-resistant resin layer forms a sealing space for sealing said organic photoelectric conversion part together with said substrates.

7. The photoelectric conversion sensor according to claim 6, wherein said moisture-resistant resin layer is arranged to avoid contact between said optical filter and said organic photoelectric conversion pixel part.

8. The photoelectric conversion sensor according to claim 6, wherein said moisture-resistant resin layer is made of a photo-setting resin.

9. The photoelectric conversion sensor according to claim 6, wherein said moisture-resistant resin layer is made of a thermosetting resin.

10. The photoelectric conversion sensor according to claim 1, wherein said support part is a moisture-resistant resin layer bonding together said substrate and said light transmissive substrate; and
said moisture-resistant resin layer has light transmission properties and is arranged to coat said organic photoelectric conversion pixel part.

11. The photoelectric conversion sensor according to claim 10, wherein said moisture-resistant resin layer is made of a thermosetting resin that may be cured at a temperature lower than the glass transition temperature of an organic material used in said organic photoelectric conversion pixel part.

12. The photoelectric conversion sensor according to claim 1, further comprising a condensing lens array arranged between said organic photoelectric conversion pixel part and said optical filter,
wherein said condensing lens array has at least one condensing lens corresponding to at least one organic photoelectric conversion pixel and condenses light that has passed through said optical filter toward said organic photoelectric conversion pixel part.

13. The photoelectric conversion sensor according to claim 12, further comprising a partition part between pixels of said organic photoelectric conversion pixel part, wherein the height of said partition part from said substrate as a reference plane is greater than that of said organic photoelectric conversion pixel part.

14. The photoelectric conversion sensor according to claim 13, wherein said partition part has light shielding properties.

15. The photoelectric conversion sensor according to claim 1, further comprising wires for electrically connecting each of said organic photoelectric conversion pixel parts to an external part and an electrically insulating layer for covering said wire,
wherein all of said wires and said electrically insulating layer are interposed between said substrate and said organic photoelectric conversion pixel part.

16. The photoelectric conversion sensor according to claim 15, wherein said organic photoelectric conversion pixel part and said wires are connected to each other with a conductive part that fills a through hole formed in said electrically insulating layer.

17. The photoelectric conversion sensor according to claim 1, wherein said organic photoelectric conversion pixel part includes a photoelectric conversion part made of an organic material between two electrodes and the electrode on the side of incident light is a transparent electrode and the electrode on the other end is a light-reflecting electrode.

18. The photoelectric conversion sensor according to claim 17, wherein said light-reflecting electrode is made of a metal film.

19. The photoelectric conversion sensor according to claim 17, wherein said transparent electrode is made of an indium-tin oxide.

20. The photoelectric conversion sensor according to claim 17, wherein the photoelectric conversion part composed of said organic material includes at least one type of electron donor material and at least one type of electron acceptance material.

21. The photoelectric conversion sensor according to claim 20, wherein at least one type of said electron donor material and said electron acceptance material is made of a polymeric material.

22. The photoelectric conversion sensor according to claim 1, wherein said substrate is larger than said light transmissive substrate in a plan view.

23. The photoelectric conversion sensor according to claim 1, wherein said plurality of organic photoelectric conversion pixel parts take the form of pixel arrangement in a linear image sensor.

24. The photoelectric conversion sensor according to claim 1, wherein said plurality of organic photoelectric conversion pixel parts take the form of pixel arrangement in an area image sensor.

25. A photoelectric conversion unit, comprising:
the photoelectric conversion sensor according to claim 1; and
an imaging optical mechanism for irradiating light onto a subject of imaging and forming an image of light from a subject of imaging.

26. An image reader, comprising:
the photoelectric conversion unit according to claim 25; and
a transfer mechanism for a subject of imaging.
